(19) United States
(12) Patent Application Publication
(10) Pub. No.: US 2025/0089311 A1
(43) Pub. Date: Mar. 13, 2025

(54) HIGH VOLTAGE MOSFET USING SHALLOW-SHALLOW TRENCH ISOLATION STRUCTURE

(71) Applicant: Taiwan Semiconductor Manufacturing Company, Ltd., Hsinchu (TW)

(72) Inventors: Hung-Chih Tsai, Daliao Township (TW); Liang-Yu Su, Yunlin County (TW); Ruey-Hsin Liu, Hsin-Chu (TW); Hsueh-Liang Chou, Jhubei City (TW); Ming-Ta Lei, Hsin-Chu City (TW)

(21) Appl. No.: 18/463,463

(22) Filed: Sep. 8, 2023

(51) Int. Cl. H01L 29/06; H01L 29/40; H01L 29/417; H01L 29/66; H01L 29/78

(52) U.S. Cl. CPC H10D 62/116; H10D 30/0281; H10D 30/65; H10D 64/111; H10D 64/251

(57) ABSTRACT

In some embodiments, the present disclosure relates to an integrated device, including a substrate comprising a channel region; a gate structure disposed on the substrate over the channel region; a first doped region of a first doping type on a first side of the gate structure; a second doped region of the first doping type on a second side of the gate structure; a shallow trench isolation (STI) structure disposed on an opposite side of the first doped region from the gate structure and having a bottom surface at a first depth beneath a top surface of the substrate; a shallow-shallow trench isolation (SSTI) structure extending from the second doped region to the gate structure, the SSTI structure having a bottom surface at a second depth beneath the top surface of the substrate, where the second depth is less than the first depth.

### BACKGROUND

Many modern day electronic devices include MOSFETs. Different types of MOSFETs may be designed to accommodate different power levels, such as low voltage MOSFETS (LVMOS) and high voltage MOSFETS (HVMOS). HVMOS devices are designed to withstand higher gate-to-drain voltages than LVMOS devices. LVMOS devices are smaller and more efficient than HVMOS devices.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates a cross-sectional view of some embodiments of an integrated chip having a shallow-shallow trench isolation (SSTI) structure beneath the gate structure.

FIGS. 2A-2F illustrate cross-sectional views of some additional embodiments of an integrated chip having a shallow-shallow trench isolation (SSTI) structure beneath the gate structure.

FIGS. 3A-3B illustrate cross-sectional views of some embodiments of an integrated chip having a shallow-shallow trench isolation (SSTI) structure separating the gate structure from the substrate.

FIGS. 4A-4D illustrate graphs of some parameters of an integrated chip having a shallow-shallow trench isolation (SSTI) structure beneath the gate structure in some embodiments.

FIGS. 5-28 illustrate cross-sectional views of some embodiments of a method of forming an integrated chip having a shallow-shallow trench isolation (SSTI) structure beneath the gate structure in some embodiments.

FIG. 29 illustrates a flow diagram of some embodiments of a method of forming an integrated chip having a shallow-shallow trench isolation (SSTI) structure beneath the gate structure in some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Metal oxide semiconductor field effect transistors (MOSFETs) are used for a variety of purposes in integrated devices, including memory, logic, and power control apparatus. The different uses for transistors use different amounts of power. Different types of MOSFETs are used to transmit signals of differing power levels. For example, high voltage MOSFETs (HVMOS) are used in power applications and other higher voltage processes. Low voltage MOSFETs (LVMOS) are used in applications where lower power levels are usable due to their smaller size and greater power efficiency. Both LVMOS and HVMOS devices may be made on the same chip, and may have an integrated process flow that accounts for the thermal and process limitations of the different types of MOSFETs.

In order to further reduce the size and profile of HVMOS devices to increase the number of devices that may fit in a chip, a thickness of a gate dielectric of the HVMOS devices may be reduced. This reduction in thickness, while lowering the profile of the device, also increases the gate leakage and channel leakage of the device. In some cases, the gate leakage of HVMOS devices with a reduced gate dielectric thickness may increase by approximately 200 times after reaching a breakdown voltage. Further, the off current of HVMOS devices with a reduced gate dielectric thickness may increase by approximately 1000 times after reaching the breakdown voltage. The increased leakage current and off current are primarily due to electron trapping occurring near a first gate edge of the gate caused by a combination of a high impact ionization rate and the voltage differential between the gate and underlying substrate. Such a change in leakage current may cause inconsistent and false readings in the circuit the HVMOS device is in, as well as inefficient power usage. Therefore, a device that maintains a thinner gate dielectric while reducing the effects of reaching the breakdown voltage is desirable. Further, additional thermal processes have an adverse effect on LVMOS devices in the same chip after doping of the LVMOS components is complete, so a device that reduces the effects of reaching the breakdown voltage without adding thermal processes after the doping processes is desirable.

The present disclosure provides an integrated device comprising a shallow-shallow trench isolation (SSTI) structure beneath the gate dielectric. The SSTI structure is disposed beneath the first gate edge of the gate structure and between the first gate edge and a source/drain region of the device. The addition of the SSTI structure replaces the substrate beneath the first gate edge, increasing the distance between a conductive gate and the substrate beneath the first gate edge. The SSTI structure effectively extends the gate dielectric into the substrate, offering the benefits of a thicker gate dielectric at the first gate edge.

Further, with the addition of the SSTI structure, the new point with the highest impact ionization is in a region at the edge of the SSTI structure. The greater distance between this region and the source/drain region, combined with the interference of the SSTI structure and the gate further extending over the SSTI structure, reduces the voltage differential between the conductive gate and the substrate. The lower voltage differential between the conductive gate and the substrate results in a decrease in the number of electron and hole traps being formed in the region when breakdown voltage is applied, significantly reducing the amount of current leakage after reaching the breakdown voltage.

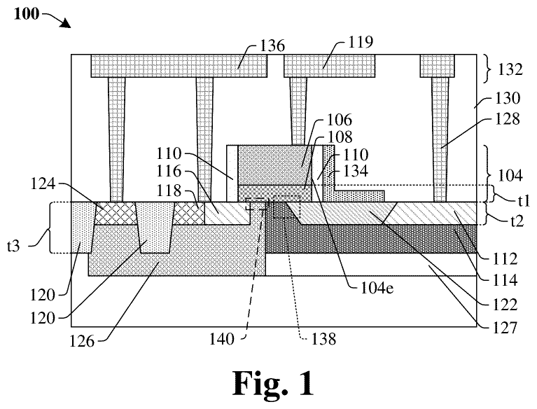

FIG. 1 illustrates a cross-sectional view 100 of some embodiments of an integrated chip having a shallow-shallow trench isolation (SSTI) structure beneath the gate structure.

A gate structure 104 comprising a gate dielectric 108 and a conductive gate 106 is disposed over a substrate 102. The gate structure 104 is surrounded by spacers 110 and is spaced on one side by a resistive protection oxide (RPO) layer 134. The gate structure 104 has a first gate edge 104e overlying an SSTI structure 122. The portion of the conductive gate 106 overlying the SSTI structure 122 acts as a field plate, resulting in the electric field at the edge of the SSTI structure 122 being less than if the first gate edge 104e was at or before the SSTI structure 122. An STI structure 120 is on an opposite side of the gate structure from the SSTI structure 122. A first source/drain region 116 borders the STI structure 120, and a second source/drain region 112 is spaced from the gate structure 104 by the SSTI structure 122. The first source/drain region 116 and the second source/drain region 112 are doped regions with a first doping type (e.g., positive doping).

A first high voltage well 114 surrounds the second source/drain region 112 and the SSTI structure 122. A first shallow well 126 surrounds portions of the STI structures 120 and extends between the first source/drain region 116 and the first high voltage well 114. The first shallow well 126 separates the first source/drain region 116 from the first high voltage well 114, forming a channel region 140 beneath the gate structure 104. The first high voltage well 114 has the first doping type and the first shallow well 126 has a second doping type different from the first doping type (e.g., negative doping). A first body region 118 and a second body region 124 are over the first shallow well 126 and have the second doping type. A second high voltage well 127 extends directly beneath the first high voltage well 114 and has the second doping type.

A dielectric layer 130 covers the gate structure 104 and the substrate 102. Contacts 128 couple the first source/drain region 116, the second source/drain region 112, the first body region 118, and the second body region 124 to a first wire level 132. In some embodiments, the first wire level 132 contains a butted-source wire 136 that is coupled to the first body region 118, the second body region 124, and the first source/drain region 116. In some embodiments, the first wire level 132 contains field plates 119 that overly the gate structure 104. In further embodiments, the field plates 119 are electrically coupled to the conductive gate 106 and terminate over the SSTI structure 122. The field plates 119 act in tandem with the portion of the conductive gate 106 overlying the SSTI structure 122 to further increase the breakdown voltage and alter the shape of the electromagnetic field.

The gate dielectric 108 has a first thickness t1. The SSTI structure 122 has a second thickness 12 that is greater than the first thickness t1. The greater thickness of the SSTI structure 122 results in a greater distance between the channel region 140 and the first gate edge 104c, improving the insulation between the first gate edge 104e and the first high voltage well 114 and displacing the region 138 with the highest impact ionization away from the first gate edge 104e (e.g., by eliminating the region with a higher impact ionization at the first gate edge). The second thickness t2 being too low (e.g., equal to or less than the first thickness t1) would maintain the region with a higher impact ionization directly beneath the gate edge, leading to a much higher gate leakage during operation, as in embodiments without an SSTI structure 122. The STI structure 120 has a third thickness t3 that is greater than the second thickness t2. The STI structure 120 has a greater thickness than the SSTI structure 122 to more effectively block the transfer of charges between different doped regions. If the second thickness t2 is too high (e.g., being equal to or greater than the third thickness t3), the SSTI structure 122 would block the first high voltage well 114 and alter the ability of the conductive gate 106 to act as a field plate, reducing the performance of the device. That is, the SSTI structure has a second thickness t2 that is greater than the first thickness t1 of the gate dielectric 108 and is less than the third thickness t3 of the STI structure 120.

The SSTI structure 122 extends beneath the gate structure 104, covering the portion of the substrate 102 beneath the first gate edge 104e. The position of the SSTI structure 122 reduces the number electron and hole traps formed beneath the first gate edge 104c. The electron and hole traps and formed due to a combination of the higher impact ionization beneath the first gate edge 104c, the voltage differential between the conductive gate 106 and the area of high impact ionization, and a high drain voltage causing a breakdown of the gate dielectric 108. By replacing the portion of the substrate 102 closest to the first gate edge 104e with an SSTI structure 122, the electron and hole traps are substantially prevented from forming within the substrate 102 at that position. With the inclusion of the SSTI structure 122, a region 138 at the edge of the SSTI structure 122 becomes the portion of the substrate with the highest impact ionization. The impact ionization at region 138 is lower than the impact ionization at the first gate edge 104e in devices with a reduced gate dielectric 108 and no SSTI structure 122. The voltage differential between the conductive gate 106 and the substrate 102 in the device is highest beneath the first gate edge 104e. The region 138 is spaced from the first gate edge 104c of the gate structure 104, resulting in a lower voltage difference between the conductive gate 106 and the substrate 102 at the region 138. The spacing of the substrate from the first gate edge 104c and the reduction in voltage difference and rate of impact ionization at the region 138 reduces the number of traps being generated due to applying the breakdown voltage.

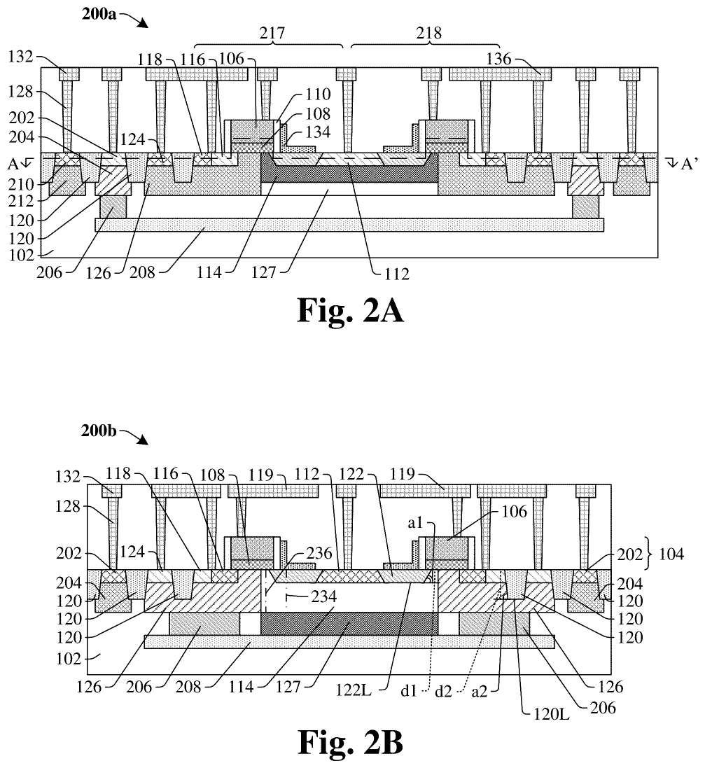

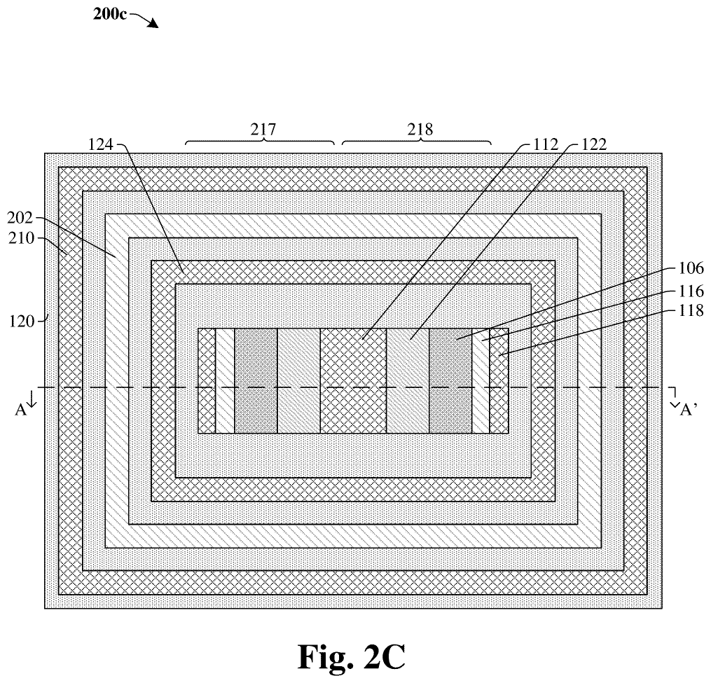

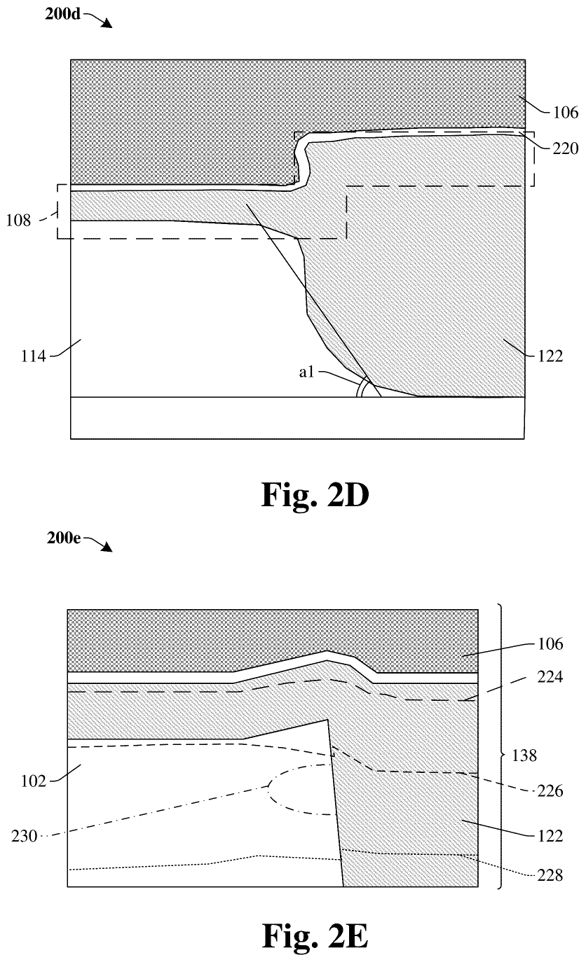

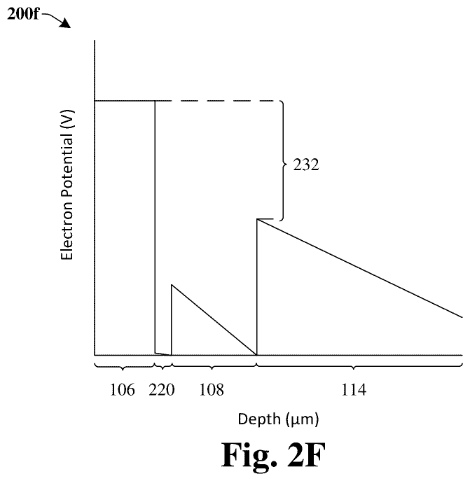

FIGS. 2A-2F illustrate cross-sectional views 200a-200f of some additional embodiments of an integrated chip having a shallow-shallow trench isolation (SSTI) structure beneath the gate structure.

As shown in the cross-sectional view 200a of FIG. 2A, in some embodiments, two or more HVMOS devices share a source/drain region on a chip. For example, a first HVMOS device 217 and a second HVMOS device 218 may be disposed around the second source/drain region 112. A first shallow ring 212 of the second doping type surrounds the first HVMOS device 217 and the second HVMOS device 218. A second shallow ring 204 of the first doping type extends between the first shallow ring 212 and the first and second HVMOS devices 217, 218. A first ring region 210 overlies the first shallow ring 212 and a second ring region 202 overlies the second shallow ring 204. Contacts 128 couple the first ring region 210 and the second ring region 202 to the first wire level 132.

In some embodiments, a first deep well 206 with the first doping type is disposed beneath the second shallow ring. A second deep well 208 is disposed beneath the first deep well and extends directly beneath the first HVMOS device 217 and the second HVMOS device 218. The first deep well 206 and the second deep well 208 surround the first and second HVMOS devices 217, 218, electrically isolating the first and second HVMOS devices 217, 218 from other components in the substrate 102.

As shown in the cross-sectional view 200b of FIG. 2B, the first and second source/drain regions 116, 112, the first and second high voltage wells 114, 127, the first shallow well 126, and the first and second body regions 118, 124 may have a different doping type than previously described. For example, the first shallow well 126, the first and second body regions 118, 124, and the second high voltage well 127 may have the first doping type, while the first and second source/drain regions 116, 112 and the first high voltage well 114 may have the second doping type. In further embodiments, the second shallow ring (see 204 of FIG. 2A) and the second ring region (see 202 of FIG. 2A) may be omitted. Further, the second high voltage well 127 may extend to the second deep well 208. Further, the first deep well 206 may extend from the first shallow well 126 to the second deep well 208.

The SSTI structure 122 has a bottom surface 122L at a first depth d1 beneath a top surface of the substrate 102. The STI structure(s) 120 have a bottom surface 120L at a second depth d2 beneath the top surface of the substrate 102. The second depth d2 is greater than the first depth d1. If the first depth d1 is equal to or greater than the second depth d2, the SSTI structure 122 would impede the transfer of charges between the channel region 140 and the second source/drain region 112 as well as alter the ability of the conductive gate 106 to act as a field plate, reducing the performance of the device. In some embodiments, a top surface of the SSTI structure(s) 122 and a top surface of the STI structure 120 are approximately at the top surface of the substrate 102. The SSTI structure 122 further has a first angle a1 between a sidewall and the bottom surface 122L of the substrate 102. The STI structure(s) 120 has a second angle a2 between a sidewall and the bottom surface 120L of the substrate 102. The first angle a1 is less than the second angle a2. A first doping profile 234 measured under the SSTI structure 122 is different from a second doping profile 236 measured under the gate dielectric 108 within the first high voltage well 114. In some embodiments, the first wire level 132 has field plates 119 that extend over the gate structure 104. The field plates 119 extend and terminate over the SSTI structure 122, and in some embodiments are electrically coupled to the conductive gate 106. The field plates are configured to distribute the electric field across the substrate 102 and increase the breakdown voltage.

As shown in the top view 200c of FIG. 2C, the second ring region 202 surrounds the first and second HVMOS devices 217, 218. Further, the second body region 124 surrounds the first and second HVMOS devices 217, 218. The first ring region 210 surrounds the second ring region 202 and the second body region 124. The first and second HVMOS devices 217, 218 are in a central region confined by the second body region 124. The first body region(s) 118 and first source/drain region(s) 116 are on opposite sides of the central region, and are separated from the second source/drain region 112 by the SSTI structure(s) 122 and the conductive gate(s) 106.

As shown in the cross-sectional view 200d of FIG. 2D, the first angle a1 is between approximately 45 to 65 degrees, approximately 40 to 60 degrees, approximately 50 to 70 degrees, or another suitable range. Over the range of angles, a reduction in the first angle a1 results in the HVMOS device having a higher breakdown voltage compared to devices with a higher angle. That is, the first angle a1 is inversely correlated to a higher breakdown voltage. The range of the first angle a1 being lower than the angle of conventional STI structures (see 120 of FIG. 1) also may reduce the voltage differential near the edge of the SSTI structure 122, increasing the reliability of the HVMOS device. In some embodiments, the gate dielectric 108 is an oxide that extends over the SSTI structure 122 and the first high voltage well 114. In some embodiments, the gate dielectric 108 is separated from the conductive gate 106 by a hafnium oxide layer 220. In some embodiments, the gate dielectric 108 has multiple upper surfaces.

As shown in the cross-sectional view 200e of FIG. 2E, the region 138 is shown in greater detail. In some embodiments, the difference in voltage between the conductive gate 106 and the substrate 102 is dominated by the gate-to-substrate coupling instead of the gate-to-drain coupling due to the addition of the SSTI structure 122. A first voltage line 224, second voltage line 226, and third voltage line 228 illustrate the voltage contour of the device in region 138. There is a difference of approximately 1 volt between the first voltage line 224 and the second voltage line 226, and there is a difference of approximately 1 volt between the second voltage line 226 and the third voltage line 228. Region 230 illustrates where the impact ionization is highest in the channel of the HVMOS device. In some embodiments, the impact ionization is approximately between 10²⁴ (1/((cm³)(s)) and 10²⁶ (1/((cm³)(s)), between 10²⁵ (1/((cm³)(s)) and 10²⁷ (1/((cm³)(s)), between 10²² (1/((cm³)(s)) and 10²⁵ (1/((cm³)(s)), or another similar range.

As shown in the graph 200f of FIG. 2F, the electron potential from the conductive gate 106 to the substrate varies. The electron potential is approximately 0 in the conductive gate 106, decreases sharply at the hafnium oxide layer 220, remains low through the gate dielectric 108, and rises at the top surface of the first high voltage well 114. In some embodiments, the difference 232 between the electron potential of the conductive gate 106 and the electron potential of the first high voltage well is approximately between 1.5 and 2 volts, between 1.7 and 2.5 volts, between 1 and 1.7 volts, or within another similar range. The difference 232 in electron potential in the region (see 138 in FIG. 2E) is lower than the difference in electron potential in the area of highest impact ionization in HVMOS devices without the SSTI structure (see 122 of FIG. 2E). The lower difference 232 results in a lower amount of damage done to the substrate (see 102 of FIG. 1) when the breakdown voltage is applied.

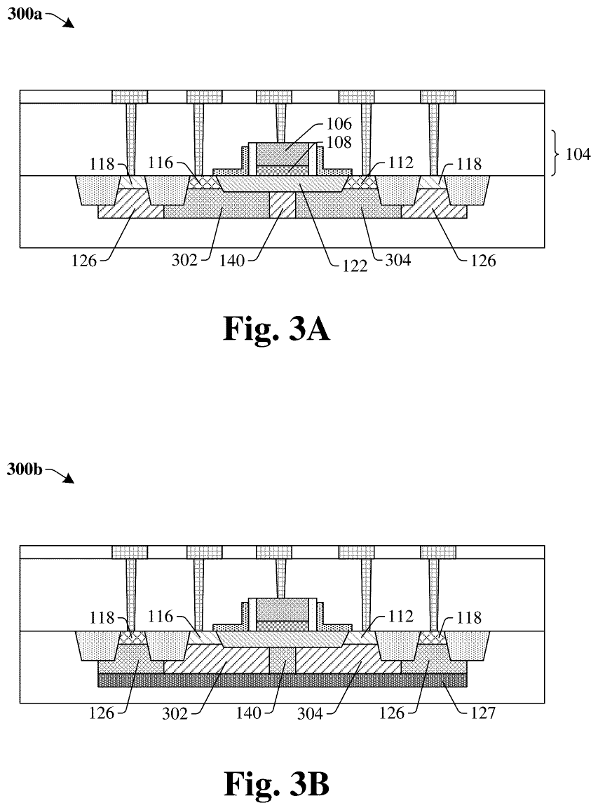

FIGS. 3A-3B illustrate cross-sectional views of some embodiments of an integrated chip having a shallow-shallow trench isolation (SSTI) structure separating the gate structure from the substrate.

As shown in the cross-sectional view 300a of FIG. 3A, the SSTI structure 122 may cover a bottom surface of the gate dielectric 108. The SSTI structure 122 separates the gate structure 104 from the substrate 102, mitigating leakage current from the gate and dielectric breakdown. In some embodiments, the first source/drain region 116 and the second source/drain region 112 are symmetrical around the gate structure 104. The first and second source/drain regions 116, 112 respectively have a first source/drain well 302 and a second source/drain well 304. The first source/drain well 302 and the second source/drain well 304 have the second doping type. The first source/drain well 302 and the second source/drain well 304 are separated by the channel region 140, wherein the channel region 140 has the first doping type. The first body region 118 and the first shallow well 126 are adjacent to the first source/drain well 302 and the second source/drain well 304 and have the first doping type.

As shown in the cross-sectional view 300b of FIG. 3B, the first and second source/drain regions 116, 112, the first and second source/drain wells 302, 304, the channel region 140, the first body region 118, and the first shallow well 126 may have different doping types than previously described. For example, the first and second source/drain regions 116, 112 and the first and second source/drain wells 302, 304 may have the first doping type, and the channel region 140, the first body region 118, and the first shallow well 126 may have the second doping type. In some embodiments, the second high voltage well is included beneath the channel region 140 and extends from a first side of the first shallow well 126 to a second side of the first shallow well 126.

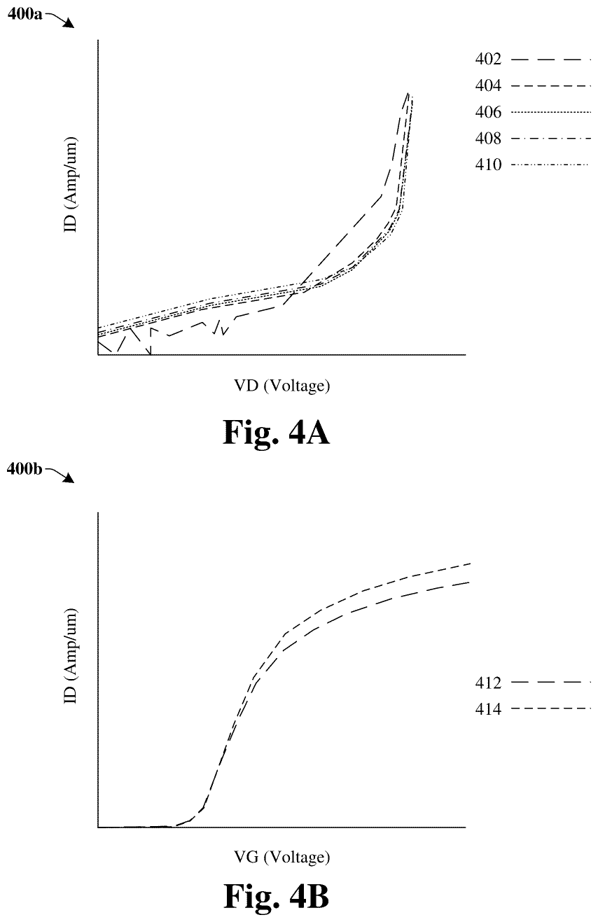

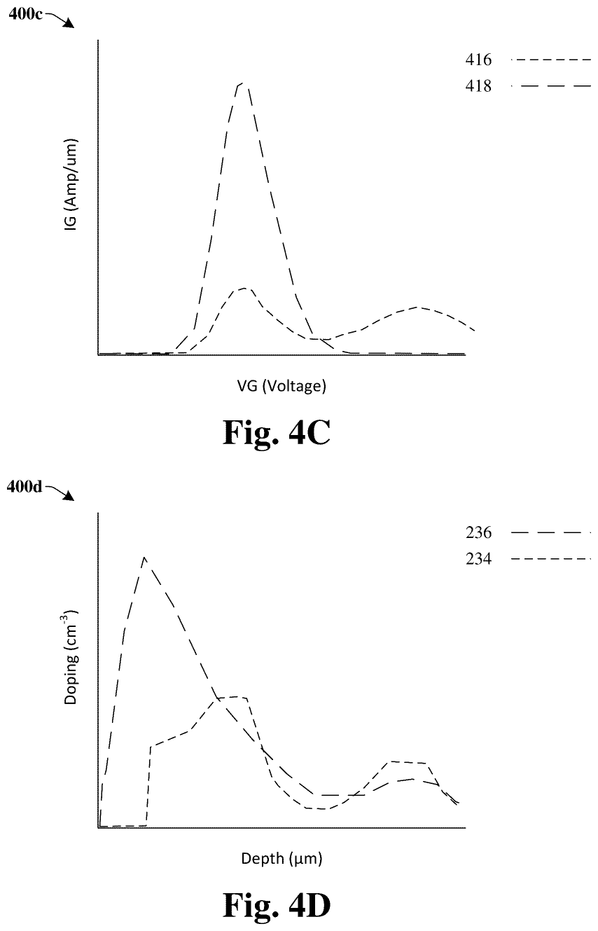

As shown in the graph 400a of FIG. 4A, the relationship between drain current and drain voltage for the HVMOS device in the off state is shown. First line 402 shows the relationship between the drain current and the drain voltage before applying a breakdown voltage to the device. A second, third, fourth, and fifth line 404, 406, 408, 410 show the relationship between the drain current and the drain voltage after applying a breakdown voltage to the device once, twice, three times, and four times, respectively. As shown, the drain current does not significantly increase after the breakdown voltage is applied. In some embodiments, the drain current may increase by approximately 2.7 times the original drain current after reaching the breakdown voltage four or more times for a range of drain voltages applied. At higher drain voltages, the drain current decreases compared to the first line 402 where the breakdown voltage was not applied. This is an improvement over HVMOS devices without the SSTI structure (see 122 of FIG. 1), which may have a drain current increase by over 1000 times the drain current before the breakdown voltage is applied.

As shown in the graph 400b of FIG. 4B, the relationship between the gate voltage and the drain current is shown. A sixth line 412 shows the relationship between the gate voltage and the drain current before the breakdown voltage is applied, and a seventh line 414 shows the relationship between the gate voltage and the drain current after the breakdown voltage is applied. As shown, after applying the breakdown voltage, a slight increase in the drain current at higher gate voltages can be seen.

As shown in the graph 400c of FIG. 4C, the relationship between the gate voltage and the gate current is shown. An eighth line 416 shows the relationship between the gate voltage and the gate current before the breakdown voltage is applied, and a ninth line 418 shows the relationship between the gate voltage and the gate current after the breakdown voltage is applied. As shown, for a range of gate voltages, the gate current is larger after the breakdown voltage is applied. In some embodiments, the maximum gate current is approximately between 4 and 5 times larger than the maximum gate current before the breakdown voltage is applied. An increase in maximum gate current between 4 and 5 times the original maximum is an improvement over HVMOS devices without the SSTI structure (see 122 of FIG. 1), which may have a maximum gate current increase to be over 200 times the original maximum gate current.

As shown in the graph 400d of FIG. 4D, the first doping profile 234 (as shown in FIG. 2B) beneath the SSTI structure (see 122 of FIG. 2B) and the second doping profile 236 (as shown in FIG. 2B) beneath the gate structure (see 104 of FIG. 2B) past the SSTI structure (see 122 of FIG. 2B) are graphed. As shown, the second doping profile 236 is inconstant and has a greater maximum concentration of dopants near the upper surface of the substrate 102 than the maximum concentration of dopants of the first doping profile 234. In some embodiments, the maximum concentration of dopants of the second doping profile 236 is approximately double the maximum concentration of dopants of the first doping profile 234.

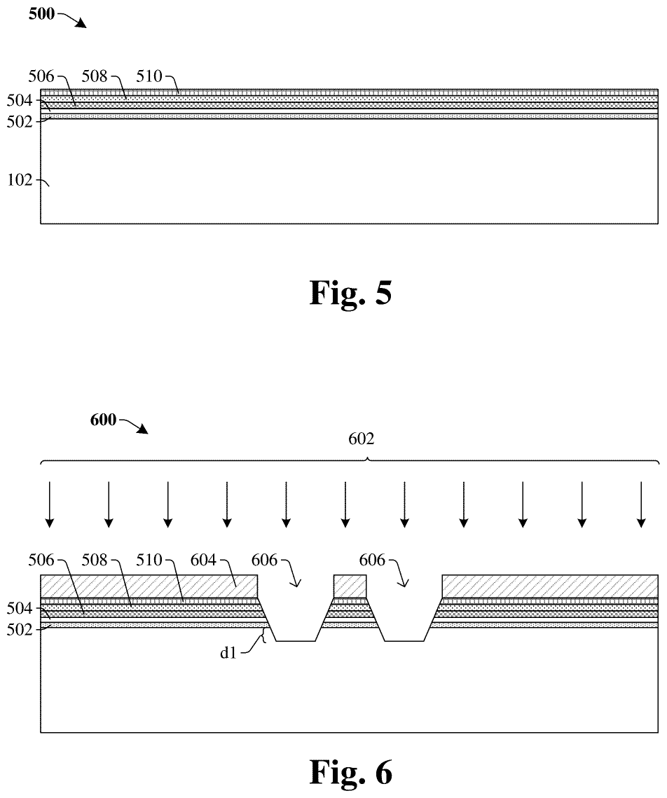

FIGS. 5-28 illustrate cross-sectional views of some embodiments of a method of forming an integrated chip having a shallow-shallow trench isolation (SSTI) structure beneath the gate structure in some embodiments. Although FIGS. 5-28 are described in relation to a method, it will be appreciated that the structures disclosed in FIGS. 5-28 are not limited to such a method, but instead may stand alone as structures independent of the method.

As shown in cross-sectional view 500 of FIG. 5, the substrate 102 is provided. A pad oxide layer 502 is formed on the substrate 102. In some embodiments, the pad oxide layer 502 is a thermal oxide. A first nitride layer 504 is formed over the pad oxide layer 502. A first tetraethyl orthosilicate (TEOS) layer 506 is formed over the first nitride layer 504. A first antireflective layer 508 is formed over the first TEOS layer 506. A first oxynitride layer 510 is formed over the first antireflective layer 508. In some embodiments, the first nitride layer 504, the first TEOS layer 506, the first antireflective layer 508, and the first oxynitride layer 510 are formed using one of chemical vapor deposition (CVD), physical vapor deposition (PVD), atomic layer deposition (ALD), some other suitable deposition process, or a combination of the foregoing. In some embodiments, the first nitride layer 504 is or comprises silicon nitride (Si₃N₄) or the like. In some embodiments, the first oxynitride layer 510 comprises silicon oxynitride (N₂OSi₂) or the like.

As shown in the cross-sectional view 600 of FIG. 6, a first masking layer 604 is formed over the first oxynitride layer 510. In some embodiments, the first masking layer 604 is a photoresist. The first masking layer 604 is then patterned. In some embodiments, the first masking layer 604 is patterned using photolithography.

A first etching process 602 is then performed. During the first etching process 602, the first oxynitride layer 510, the first antireflective layer 508, the first TEOS layer 506, the first nitride layer 504, the pad oxide layer 502, and the substrate 102 are etched in the regions that are exposed by the first masking layer 604. In some embodiments, first etching process 602 may be a dry etch such as a plasma etch or the like. The first etching process 602 results in first openings 606 formed in the substrate 102. The first openings 606 extend to a first depth d1 within the substrate 102. The first masking layer 604 is subsequently removed.

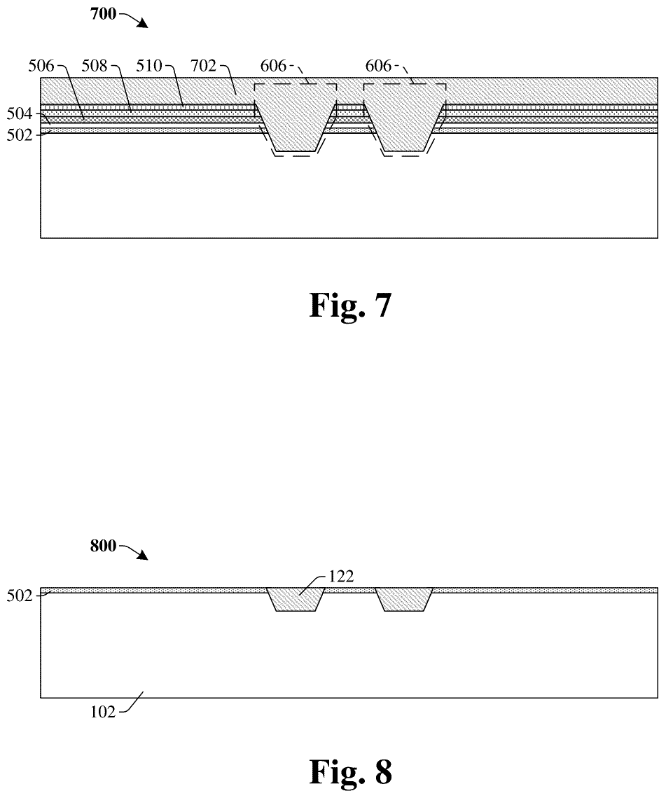

As shown in cross-sectional view 700 of FIG. 7, a first conformal oxide layer 702, is deposited over the upper surface of the first oxynitride layer 510, filling the first openings 606 (shown in phantom). In some embodiments, the first conformal oxide layer 702 may be deposited using one of thermal oxidation, CVD, PVD, ALD, some other suitable deposition process, or a combination of the foregoing. In some embodiments, the first conformal oxide layer 702 comprises a lining oxide formed using thermal oxidation and a high aspect ratio process (HARP) oxide deposited using CVD. In some embodiments, the first conformal oxide layer 702 is or comprises silicon dioxide (SiO₂).

As shown in cross-sectional view 800 of FIG. 8, the first oxynitride layer 510 (see FIG. 7), the first antireflective layer 508 (see FIG. 7), the first TEOS layer 506 (see FIG. 7), the first nitride layer 504 (see FIG. 7) are removed, exposing an upper surface of the pad oxide layer 502. In some embodiments, the first oxynitride layer 510 (see FIG. 7), the first antireflective layer 508 (see FIG. 7), and the first TEOS layer 506 (see FIG. 7) are removed using a planarization process (e.g., a chemical mechanical planarization (CMP) process). In further embodiments, the first nitride layer 504 is removed using phosphoric acid (H₃PO₄) after the planarization process. The removal of the portions of the first conformal oxide layer 702 (see FIG. 7) above the pad oxide layer 502 due to the planarization process results in the SSTI structures 122 remaining in the substrate 102.

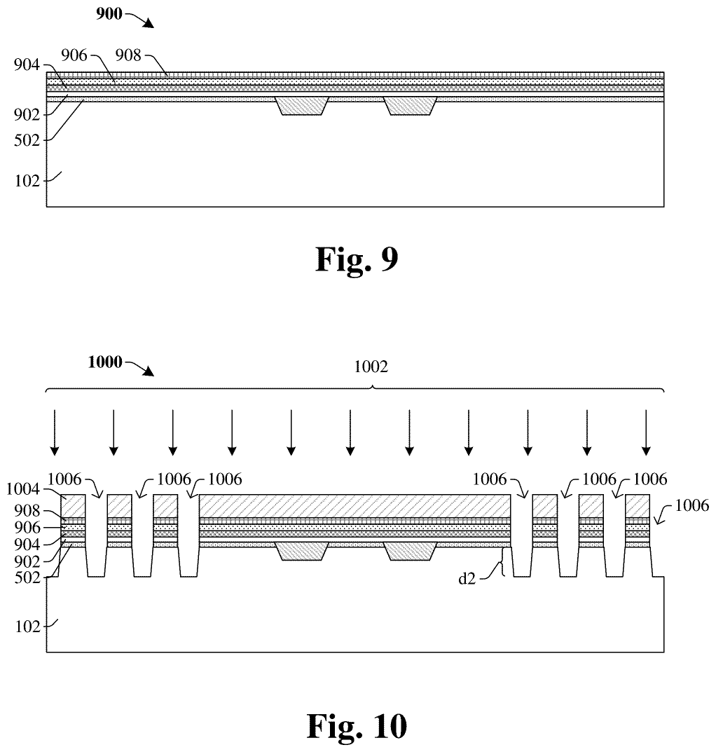

As shown in cross-sectional view 900 of FIG. 9, a second nitride layer 902 is formed over the pad oxide layer 502. A second TEOS layer 904 is formed over the second nitride layer 902. A second antireflective layer 906 is formed over the second TEOS layer 904. A second oxynitride layer 908 is formed over the second antireflective layer 906. In some embodiments, the second nitride layer 902, the second TEOS layer 904, the second antireflective layer 906, and the second oxynitride layer 908 are formed using one of CVD, PVD, ALD, some other suitable deposition process, or a combination of the foregoing. In some embodiments, the second nitride layer 902 is or comprises silicon nitride (Si₃N₄) or the like. In some embodiments, the second oxynitride layer 908 comprises silicon oxynitride (N₂OSi₂) or the like.

As shown in the cross-sectional view 1000 of FIG. 10, a second masking layer 1004 is formed over the second oxynitride layer 908. In some embodiments, the second masking layer 1004 is a photoresist. The second masking layer 1004 is then patterned. In some embodiments, the second masking layer 1004 is patterned using photolithography.

A second etching process 1002 is then performed. During the second etching process 1002, the second oxynitride layer 908, the second antireflective layer 906, the second TEOS layer 904, the second nitride layer 902, the pad oxide layer 502, and the substrate 102 are etched in the regions that are exposed by the second masking layer 1004. In some embodiments, second etching process 1002 may be a dry etch such as a plasma etch or the like. The second etching process 1002 results in second openings 1006 formed in the substrate 102. The second openings 1006 extend to a second depth d2 within the substrate 102. The second masking layer 1004 is subsequently removed.

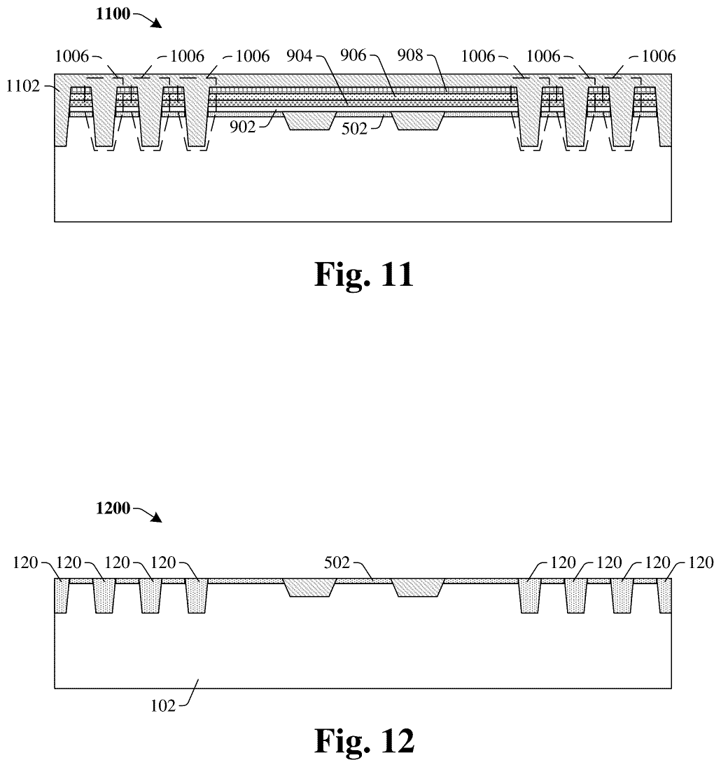

As shown in cross-sectional view 1100 of FIG. 11, a second conformal oxide layer 1102, is deposited over the upper surface of the second oxynitride layer 908, filling the second openings 1006 (shown in phantom). In some embodiments, the second conformal oxide layer 1102 may be deposited using one of thermal oxidation, CVD, PVD, ALD, some other suitable deposition process, or a combination of the foregoing. In some embodiments, the second conformal oxide layer 1102 comprises a lining oxide formed using thermal oxidation and a high aspect ratio process (HARP) oxide deposited using CVD. In some embodiments, the second conformal oxide layer 1102 is or comprises silicon dioxide (SiO₂) or the like. In some embodiments, the second conformal oxide layer 1102 comprises a same material as the first conformal oxide layer (see 702 of FIG. 7).

As shown in cross-sectional view 1200 of FIG. 12, the second oxynitride layer 908 (see FIG. 11), the second antireflective layer 906 (see FIG. 11), the second TEOS layer 904 (see FIG. 11), the second nitride layer 902 (see FIG. 11) are removed, exposing an upper surface of the pad oxide layer 502. In some embodiments, the second oxynitride layer 908 (see FIG. 11), the second antireflective layer 906 (see FIG. 11), and the second TEOS layer 904 (see FIG. 11) are removed using a planarization process (e.g., a chemical mechanical planarization (CMP) process). In further embodiments, the second nitride layer 902 is removed using phosphoric acid (H₃PO₄) after the planarization process. The removal of the portions of the second conformal oxide layer 1102 (see FIG. 11) above the pad oxide layer 502 due to the planarization process results in the STI structures 120 remaining in the substrate 102.

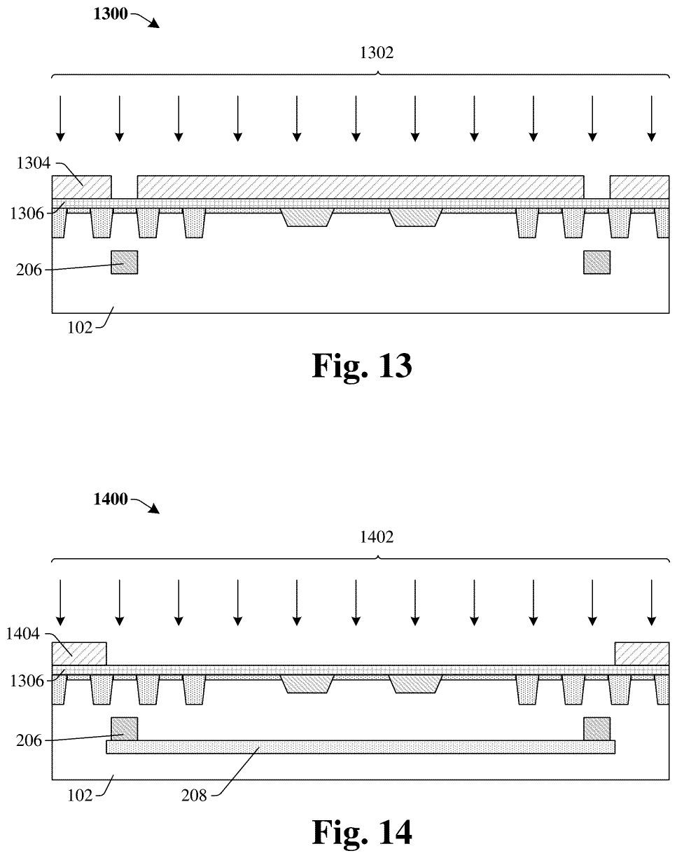

As shown in the cross-sectional view 1300 of FIG. 13, a sacrificial oxide layer 1306 is formed over the substrate 102. A third masking layer 1304 is formed over the sacrificial oxide layer 1306. In some embodiments, the third masking layer 1304 is a photoresist. The third masking layer 1304 is then patterned. In some embodiments, the third masking layer 1304 is patterned using photolithography. A first implantation process 1302 is then performed. The first implantation process 1302 implants dopants according to the pattern of the third masking layer 1304, resulting in a first deep well 206 with the first doping type being formed. The third masking layer 1304 is subsequently removed.

As shown in the cross-sectional view 1400 of FIG. 14, a fourth masking layer 1404 is formed over the sacrificial oxide layer 1306. In some embodiments, the fourth masking layer 1404 is a photoresist. The fourth masking layer 1404 is then patterned. In some embodiments, the fourth masking layer 1404 is patterned using photolithography. A second implantation process 1402 is then performed. The second implantation process 1402 implants dopants according to the pattern of the fourth masking layer 1404, resulting in a second deep well 208 with the first doping type being formed beneath the first deep well 206. The fourth masking layer 1404 is subsequently removed.

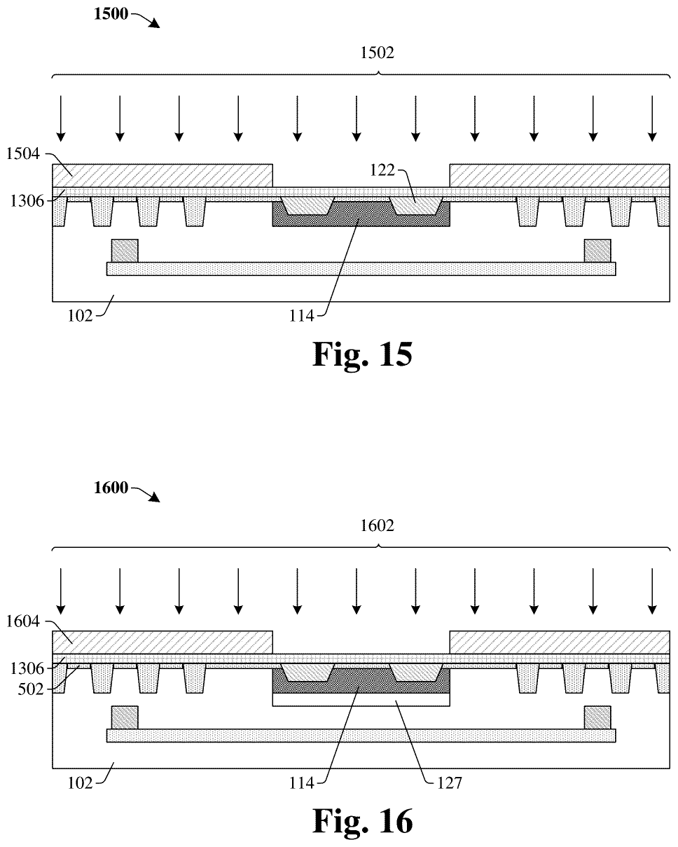

As shown in the cross-sectional view 1500 of FIG. 15, a fifth masking layer 1504 is formed over the sacrificial oxide layer 1306. In some embodiments, the fifth masking layer 1504 is a photoresist. The fifth masking layer 1504 is then patterned. In some embodiments, the fifth masking layer 1504 is patterned using photolithography. A third implantation process 1502 is then performed. The third implantation process 1502 implants dopants according to the pattern of the fifth masking layer 1504, resulting in a first high voltage well 114 of the first doping type surrounding the SSTI structures 122. The fifth masking layer 1504 is subsequently removed.

As shown in the cross-sectional view 1600 of FIG. 16, a sixth masking layer 1604 is formed over the sacrificial oxide layer 1306. In some embodiments, the sixth masking layer 1604 is a photoresist. The sixth masking layer 1604 is then patterned. In some embodiments, the sixth masking layer 1604 is patterned using photolithography. A fourth implantation process 1602 is then performed. The fourth implantation process 1602 implants dopants according to the pattern of the sixth masking layer 1604, resulting in a second high voltage well 127 of the second doping type directly beneath the first high voltage well 114 of the first doping type. The sixth masking layer 1604, the sacrificial oxide layer 1306, and the pad oxide layer 502 are subsequently removed.

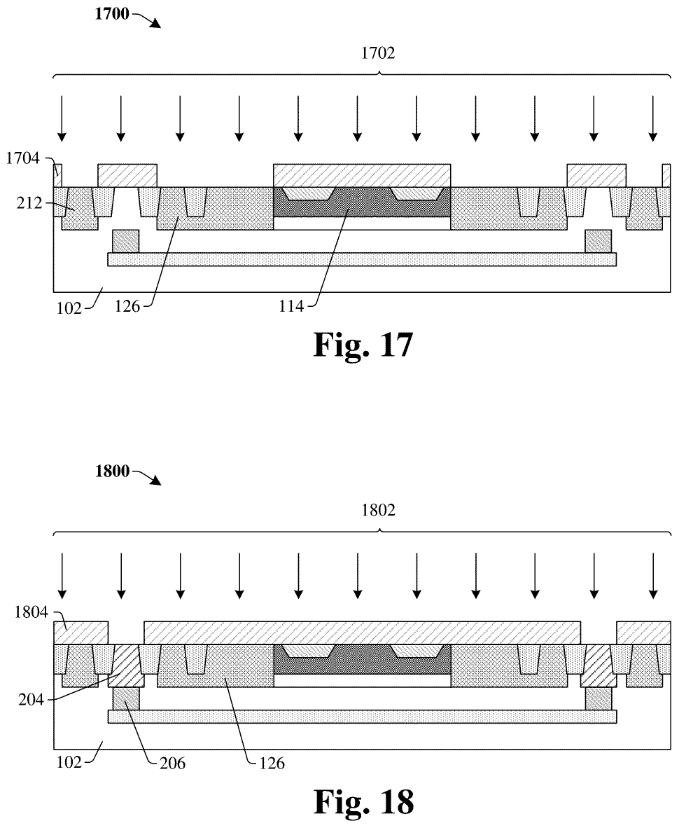

As shown in the cross-sectional view 1700 of FIG. 17, a seventh masking layer 1704 is formed over the substrate 102. In some embodiments, the seventh masking layer 1704 is a photoresist. The seventh masking layer 1704 is then patterned. In some embodiments, the seventh masking layer 1704 is patterned using photolithography. A fifth implantation process 1702 is then performed. The fifth implantation process 1702 implants dopants according to the pattern of the seventh masking layer 1704, resulting in a first shallow well 126 and a first shallow ring 212 of the second doping type surrounding the first high voltage well 114. The seventh masking layer 1704 is subsequently removed.

As shown in the cross-sectional view 1800 of FIG. 18, an eighth masking layer 1804 is formed over the substrate 102. In some embodiments, the eighth masking layer 1804 is a photoresist. The eighth masking layer 1804 is then patterned. In some embodiments, the eighth masking layer 1804 is patterned using photolithography. A sixth implantation process 1802 is then performed. The sixth implantation process 1802 implants dopants according to the pattern of the eighth masking layer 1804, resulting in a second shallow ring 204 of the first doping type surrounding the first shallow well 126 and directly above the first deep well 206. The eighth masking layer 1804 is subsequently removed.

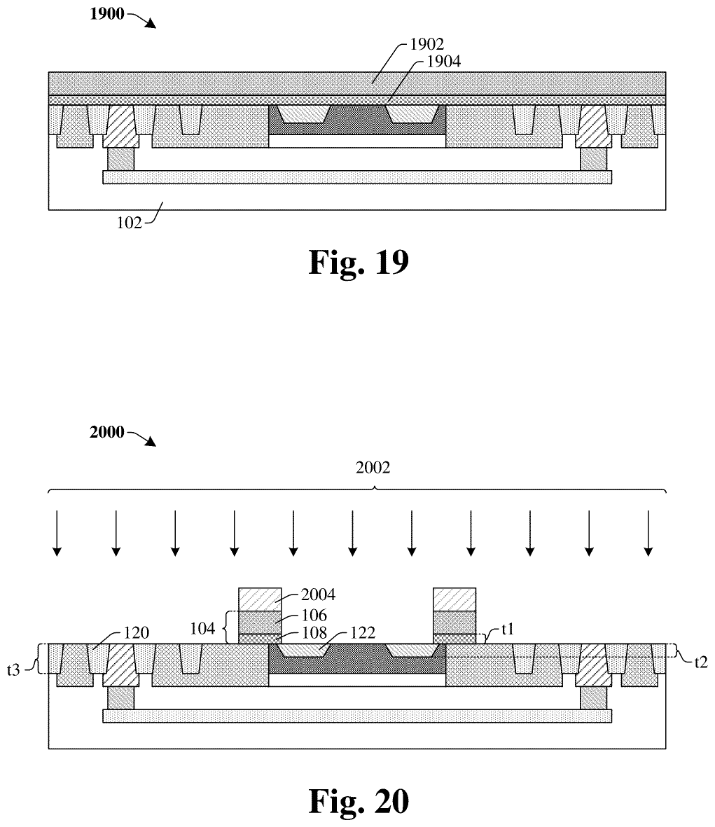

As shown in the cross-sectional view 1900 of FIG. 19, a gate dielectric material 1904 and a gate material 1902 are deposited over the substrate. In some embodiments, the gate dielectric material 1904 is or comprises an oxide, a high-k dielectric, or the like. In some embodiments, the gate material 1902 is or comprises polysilicon, metal, or the like.

As shown in the cross-sectional view 2000 of FIG. 20, a ninth masking layer 2004 is formed over the gate material 1902. In some embodiments, the ninth masking layer 2004 is a photoresist. The ninth masking layer 2004 is then patterned. In some embodiments, the ninth masking layer 2004 is patterned using photolithography.

A third etching process 2002 is then performed. During the third etching process 2002, the gate dielectric material (see 1904 of FIG. 19) and the gate material (see 1902 of FIG. 19) are etched in the regions that are exposed by the ninth masking layer 2004. In some embodiments, third etching process 2002 may be a dry etch such as a plasma etch or the like. The third etching process 2002 results in the gate dielectric 108 and the conductive gate 106 remaining on the substrate 102 and having a first gate edge 104e directly over the SSTI structure 122. In some embodiments, a portion of the gate structure 104 directly over the SSTI structure 122 has a length between approximately 0.01 micrometers and 90% of a length of the SSTI structure 122. The ninth masking layer 2004 is subsequently removed.

In some embodiments, the first thickness t1 of the gate dielectric 108 is between approximately 20 angstroms and 100 angstroms, between approximately 10 angstroms and 70 angstroms, between approximately 30 angstroms and 150 angstroms, or another similar range. In some embodiments, the second thickness t2 of the SSTI structure 122 is between approximately 200 angstroms and 1200 angstroms, approximately 150 and 900 angstroms, between 250 and 1500 angstroms, or another suitable range. In some embodiments, the third thickness t3 of the STI structures 120 is between approximately 2000 angstroms and 4500 angstroms, approximately 1600 and 3600 angstroms, between 2400 and 5400 angstroms, or another suitable range.

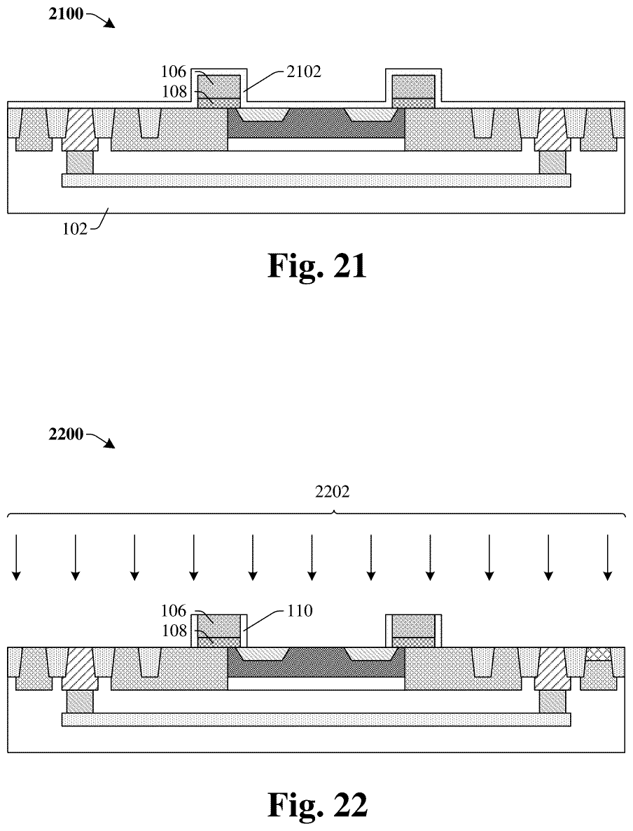

As shown in the cross-sectional view 2100 of FIG. 21, a conformal spacer layer 2102 is deposited over the substrate 102. In some embodiments, the conformal spacer layer 2102 is or comprises an insulative material such as an oxide (e.g., silicon oxide) or the like.

As shown in the cross-sectional view 2200 of FIG. 22, a fourth etching process 2202 is performed, removing horizontal portions of the conformal spacer layer (see 2102 of FIG. 21) without removing vertical portions of the conformal spacer layer (see 2102 of FIG. 21). The remaining vertical portions (e.g., the portions on the sidewalls of the conductive gate 106 and the gate dielectric 108) form the spacers 110.

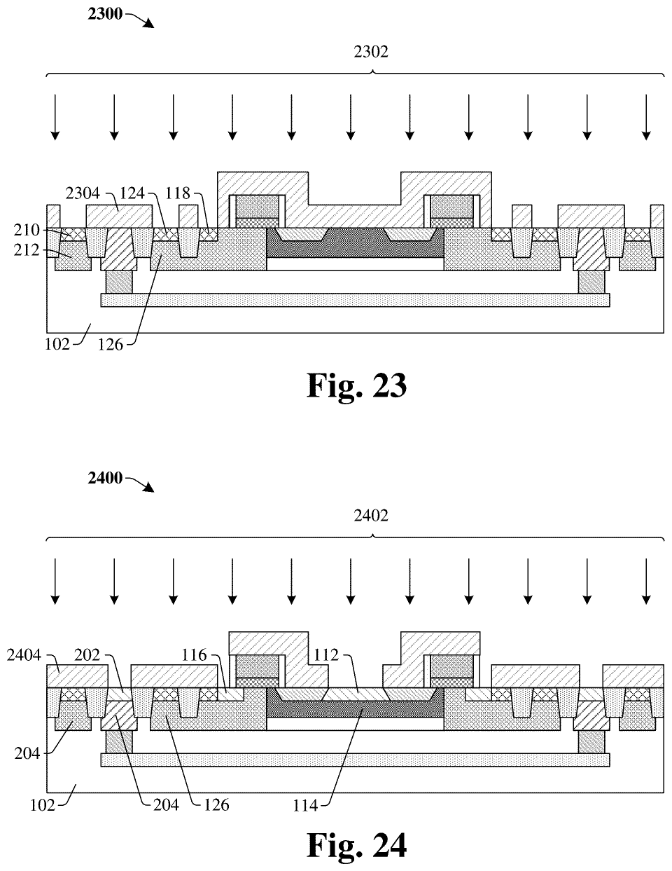

As shown in the cross-sectional view 2300 of FIG. 23, a tenth masking layer 2304 is formed over the substrate 102. In some embodiments, the tenth masking layer 2304 is a photoresist. The tenth masking layer 2304 is then patterned. In some embodiments, the tenth masking layer 2304 is patterned using photolithography. A seventh implantation process 2302 is then performed. The seventh implantation process 2302 implants dopants according to the pattern of the tenth masking layer 2304, resulting in a first body region 118, a second body region 124, and a first ring region 210 of the second doping type formed in the first shallow well 126 and the first shallow ring 212. The tenth masking layer 2304 is subsequently removed.

As shown in the cross-sectional view 2400 of FIG. 24, an eleventh masking layer 2404 is formed over the substrate 102. In some embodiments, the eleventh masking layer 2404 is a photoresist. The eleventh masking layer 2404 is then patterned. In some embodiments, the eleventh masking layer 2404 is patterned using photolithography. An eighth implantation process 2402 is then performed. The eighth implantation process 2402 implants dopants according to the pattern of the eleventh masking layer 2404, resulting in a first source/drain region 116, a second source/drain region 112, and a second ring region 202 of the first doping type formed in the first shallow well 126, and the first high voltage well 114, and the second shallow ring 204 respectively. The eleventh masking layer 2404 is subsequently removed.

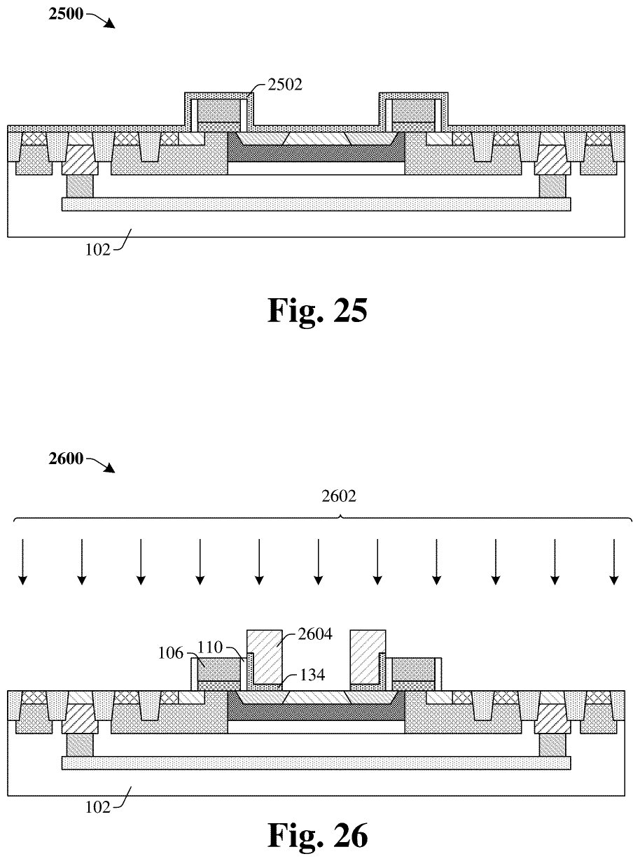

As shown in the cross-sectional view 2500 of FIG. 25, a conformal RPO 2502 is deposited over the substrate 102. In some embodiments, the conformal RPO 2502 is or comprises an insulative material such as an oxide (e.g., silicon oxide) or the like.

As shown in the cross-sectional view 2600 of FIG. 26, a twelfth masking layer 2604 is formed over the substrate 102. In some embodiments, the twelfth masking layer 2604 is a photoresist. The twelfth masking layer 2604 is then patterned. In some embodiments, the twelfth masking layer 2604 is patterned using photolithography.

A fifth etching process 2602 is then performed. During the fifth etching process 2602, the conformal RPO (see 2502 of FIG. 25) are etched in the regions that are exposed by the twelfth masking layer 2604. In some embodiments, fifth etching process 2602 may be a dry etch such as a plasma etch or the like. The fifth etching process 2602 results in the RPO layer 134 remaining on the substrate 102 along sidewalls of the spacers 110. The RPO layer 134 has an “L” shaped profile when viewed from a cross-sectional view. The twelfth masking layer 2604 is subsequently removed. After the twelfth masking layer 2604 is removed, a silicide layer is formed over the substrate 102 and the conductive gate 106. The silicide layer is configured to lower the contact resistance between the substrate 102 and the contacts to be formed hereafter (scc 128 of FIG. 28).

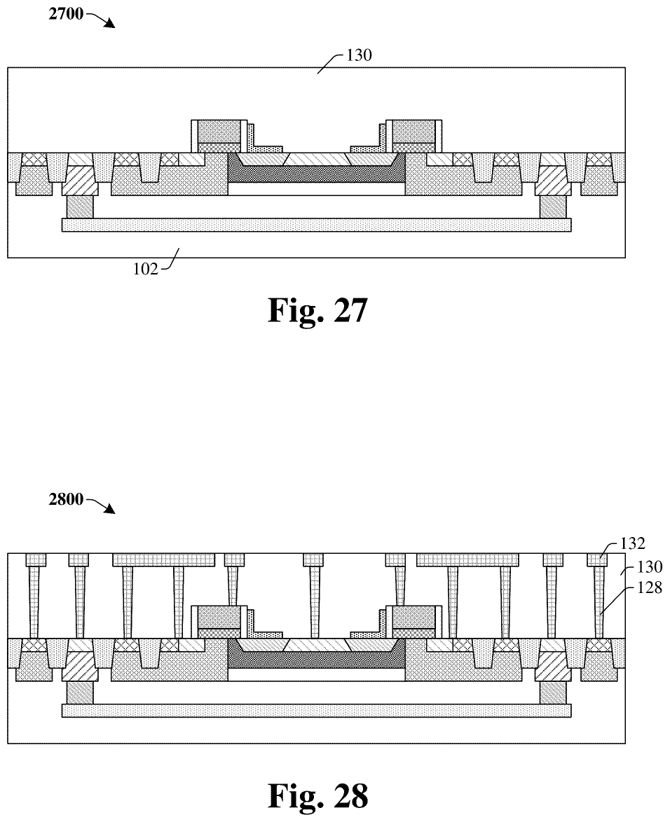

As shown in the cross-sectional view 2700 of FIG. 27, a dielectric layer 130 is formed over the substrate 102. In some embodiments, the dielectric layer 130 is or comprises an oxide (e.g., silicon oxide (SiO₂)) or the like. In some embodiments, the dielectric layer 130 is formed using a deposition process (e.g., a CVD process).

As shown in the cross-sectional view 2800 of FIG. 28, the contacts 128 and the first wire level 132 are formed within the dielectric layer 130. In some embodiments the contacts 128 and the first wire level 132 comprises a conductive material, such as copper (Cu), nickel (Ni), titanium (Ti), or the like.

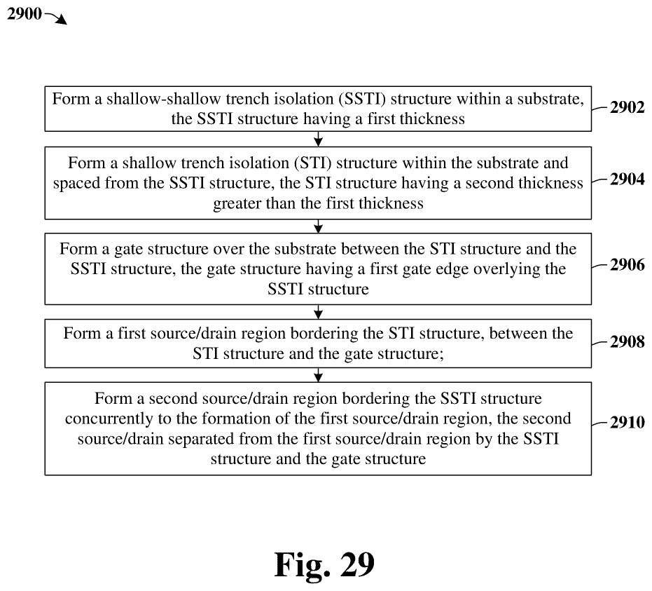

FIG. 29 illustrates a flow diagram 2900 of some embodiments of a method of forming an integrated chip having a shallow-shallow trench isolation (SSTI) structure beneath the gate structure in some embodiments.

While method 2900 is illustrated and described below as a series of acts or events, it will be appreciated that the illustrated ordering of such acts or events are not to be interpreted in a limiting sense. For example, some acts may occur in different orders and/or concurrently with other acts or events apart from those illustrated and/or described herein. In addition, not all illustrated acts may be required to implement one or more aspects or embodiments of the description herein. Further, one or more of the acts depicted herein may be carried out in one or more separate acts and/or phases.

At 2902, a shallow-shallow trench isolation (SSTI) structure is formed within the substrate, the SSTI structure having a first thickness. FIGS. 5-8 illustrate cross-sectional views 500-800 of some embodiments corresponding to act 2902.

At 2904, a shallow trench isolation (STI) structure is formed within the substrate and spaced from the SSTI structure, the STI structure having a second thickness greater than the first thickness. FIGS. 9-12 illustrate cross-sectional views 900-1200 of some embodiments corresponding to act 2904.

At 2906, a gate structure is formed over the substrate between the STI structure and the SSTI structure, the gate structure having a first gate edge overlying the SSTI structure. FIGS. 19-20 illustrate cross-sectional views 1900-2000 of some embodiments corresponding to act 2906.

At 2908, a first source/drain region is formed bordering the STI structure, between the STI structure and the gate structure. FIG. 24 illustrates a cross-sectional view 2400 of some embodiments corresponding to act 2908.

At 2910, a second source/drain region is formed bordering the SSTI structure concurrently to the formation of the first source/drain region, the second source/drain separated from the first source/drain region by the SSTI structure and the gate structure. FIG. 24 illustrates a cross-sectional view 2400 of some embodiments corresponding to act 2910.

Therefore, the present disclosure relates to a new method of forming an integrated chip having a plurality of capacitors with bottom electrode structures of different depths and widths.

Accordingly, in some embodiments, the present disclosure relates to an integrated device, including a substrate comprising a channel region; a gate structure disposed on the substrate over the channel region; a first doped region of a first doping type on a first side of the gate structure; a second doped region of the first doping type on a second side of the gate structure; a shallow trench isolation (STI) structure disposed on an opposite side of the first doped region from the gate structure and having a bottom surface at a first depth beneath a top surface of the substrate; a shallow-shallow trench isolation (SSTI) structure extending from the second doped region to the gate structure, the SSTI structure having a bottom surface at a second depth beneath the top surface of the substrate, where the second depth is less than the first depth.

In other embodiments, the present disclosure relates to an integrated device, including a substrate; a conductive gate disposed over the substrate; a gate dielectric separating the conductive gate from the substrate and having a first thickness; a first source/drain region on a first side of the gate structure; a second source/drain region on a second side of the gate structure; a shallow trench isolation (STI) structure bordering the first source/drain region and having a second thickness greater than the first thickness; a shallow-shallow trench isolation (SSTI) structure between the second source/drain region and the gate structure, the SSTI structure having a third thickness between the first thickness and the second thickness.

In yet other embodiments, the present disclosure relates to a method of forming an integrated device, including receiving a substrate; forming a shallow-shallow trench isolation (SSTI) structure within the substrate, the SSTI structure having a first thickness; forming a shallow trench isolation (STI) structure within the substrate and spaced from the SSTI structure, the STI structure having a second thickness greater than the first thickness; forming a gate structure over the substrate between the STI structure and the SSTI structure, the gate structure having a first sidewall overlying the SSTI structure; forming a first source/drain region bordering the STI structure, between the STI structure and the gate structure; forming a second source/drain region bordering the SSTI structure concurrently to the formation of the first source/drain region, the second source/drain separated from the first source/drain region by the SSTI structure and the gate structure.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. An integrated device, comprising:
a substrate comprising a channel region;
a gate structure disposed on the substrate over the channel region;
a first doped region of a first doping type on a first side of the gate structure;
a second doped region of the first doping type on a second side of the gate structure;
a shallow trench isolation (STI) structure disposed on an opposite side of the first doped region from the gate structure and having a bottom surface at a first depth beneath a top surface of the substrate; and
a shallow-shallow trench isolation (SSTI) structure extending from the second doped region to the gate structure, the SSTI structure having a bottom surface at a second depth beneath the top surface of the substrate.

2. The integrated device of claim 1, wherein the STI structure and the SSTI structure comprise a same material.

3. The integrated device of claim 1, wherein a first sidewall of the gate structure overlies the SSTI structure.

4. The integrated device of claim 3, wherein the gate structure extends past outer sidewalls of the SSTI structure.

5. The integrated device of claim 1, wherein the SSTI structure has sidewalls disposed at a first angle to a bottom surface of the substrate, and the STI structure has sidewalls disposed at a second angle to a bottom surface of the substrate, and wherein the first angle is less than the second angle.

6. The integrated device of claim 1, wherein the second depth is less than the first depth.

7. An integrated device, comprising:
a substrate;
a conductive gate disposed over the substrate;
a gate dielectric separating the conductive gate from the substrate and having a first thickness;
a first source/drain region on a first side of the conductive gate;
a second source/drain region on a second side of the conductive gate;
a shallow trench isolation (STI) structure bordering the first source/drain region and having a second thickness greater than the first thickness; and
a shallow-shallow trench isolation (SSTI) structure between the second source/drain region and the conductive gate, the SSTI structure having a third thickness between the first thickness and the second thickness.

8. The integrated device of claim 7, wherein the SSTI structure contacts the second source/drain region and the gate dielectric.

9. The integrated device of claim 7, further comprising a source/drain extension contacting the second source/drain region and extending between the SSTI structure and the STI structure.

10. The integrated device of claim 7, further comprising a field plate extending over the conductive gate, the field plate terminating over the SSTI structure between the conductive gate and the second source/drain region.

11. The integrated device of claim 10, further comprising:
a first source/drain contact coupled to the first source/drain region; and
a doped region adjacent to the first source/drain region contacting the first source/drain contact, wherein the doped region has a positive doping.

12. The integrated device of claim 7, wherein the first source/drain region and the second source/drain region have a positive doping.

13. A method of forming an integrated device, the method comprising:
receiving a substrate;
forming a shallow-shallow trench isolation (SSTI) structure within the substrate, the SSTI structure having a first thickness;
forming a shallow trench isolation (STI) structure within the substrate and spaced from the SSTI structure, the STI structure having a second thickness greater than the first thickness;
forming a gate structure over the substrate between the STI structure and the SSTI structure, the gate structure having a first gate edge overlying the SSTI structure;
forming a first source/drain region bordering the STI structure, between the STI structure and the gate structure; and
forming a second source/drain region bordering the SSTI structure concurrent with the forming of the first source/drain region, the second source/drain region separated from the first source/drain region by the SSTI structure and the gate structure.

14. The method of claim 13, wherein forming the SSTI structure further comprises:
forming a pad oxide layer and a nitride layer;
etching a first trench into the substrate, the first trench having sidewalls extending at an angle from a top surface of the substrate of less than 70 degrees;
filling the first trench with a conformal oxide layer; and
removing portions of the conformal oxide layer and the nitride layer above the pad oxide layer, resulting in the SSTI structure.

15. The method of claim 13, further comprising:
forming a doped region adjacent to the first source/drain region, the doped region having a different doping type than a doping of the first source/drain region.

16. The method of claim 13, further comprising:
forming a first source/drain extension surrounding the second source/drain region and extending beneath the gate structure, wherein the first source/drain extension has an inconstant doping profile.

17. The method of claim 16, wherein the first source/drain extension has a first maximum concentration of dopants in portions directly beneath the SSTI structure, and the first source/drain extension has a second maximum concentration of dopants in portions directly beneath the gate structure and extending past outer sidewalls of the SSTI structure, where the second maximum concentration of dopants is greater than the first maximum concentration of dopants.

18. The method of claim 13, further comprising:
forming a resistive protection oxide bordering a first sidewall of the gate structure and extending across an upper surface of the SSTI structure, wherein the resistive protection oxide has an “L” shaped profile when viewed from a cross-sectional view.

19. The method of claim 13, further comprising:
forming contacts coupled to the gate structure, the first source/drain region, and the second source/drain region; and
forming a wire level coupled to the contacts.

20. The method of claim 19, further comprising:
forming a body region before forming the first source/drain region separated from the first source/drain region by the STI structure, wherein a contact of the contacts is coupled to the body region, and wherein a wire of the wire level electrically couples the body region to the first source/drain region.
